(19) United States
(12) Patent Application Publication
(10) Pub. No.: US 2024/0387620 A1
(43) Pub. Date: Nov. 21, 2024

(54) MOSFETS WITH IMPLANTED CHARGE COMPENSATION REGIONS

(71) Applicant: Wolfspeed, Inc., Durham, NC (US)

(72) Inventors: Kijeong Han, Apex, NC (US); Jeff Kim, Cary, NC (US); Sei-Hyung Ryu, Cary, NC (US); Daniel Lichtenwalner, Raleigh, NC (US)

(21) Appl. No.: 18/598,866

(22) Filed: Mar. 7, 2024

Related U.S. Application Data
(60) Provisional application No. 63/466,479, filed on May 15, 2023.

(51) Int. Cl. H01L 29/06; H01L 21/04; H01L 29/16; H01L 29/66; H01L 29/78

(52) U.S. Cl. CPC H01L 29/0634; H01L 21/046; H01L 29/0696; H01L 29/1608; H01L 29/66068; H01L 29/7802

(57) ABSTRACT

A semiconductor device includes a semiconductor layer having a first conductivity type, a well region in the semiconductor layer, the well region having a second conductivity type opposite the first conductivity type, a source region having the first conductivity type in the well region, and an implanted charge compensation region in the semiconductor layer beneath the well region. The source region is adjacent a channel region in the well region. A method of forming a semiconductor device includes forming a well region having a second conductivity type in a semiconductor layer having a first conductivity type opposite the second conductivity type, forming a source region having the first conductivity type in the well region, and implanting ions into the semiconductor layer to form a charge compensation region in the semiconductor layer beneath the well region. The source region is adjacent a channel region in the well region.

### FIELD

The present disclosure relates to semiconductor devices and, more particularly, to power semiconductor switching devices.

### BACKGROUND

The Metal Oxide Semiconductor Field Effect Transistor (“MOSFET”) is a well known type of semiconductor transistor that may be used as a switching device. A MOSFET is a three terminal device that includes a source region and a drain region that are separated by a channel region, and a gate electrode that is disposed adjacent the channel region. A MOSFET may be turned on or off by applying a gate bias voltage to the gate electrode. When a MOSFET is turned on (i.e., it is in its “on-state”), current is conducted through the channel region of the MOSFET between the source region and the drain region. When the bias voltage is removed from the gate electrode (or reduced below a threshold level), the current ceases to conduct through the channel region. By way of example, an n-type MOSFET has n-type source and drain regions and a p-type channel. An n-type MOSFET thus has an “n-p-n” design. An n-type MOSFET turns on when a gate bias voltage is applied to the gate electrode that is sufficient to create a conductive n-type inversion layer in the p-type channel region that electrically connects the n-type source and drain regions, thereby allowing for majority carrier conduction therebetween.

The gate electrode of a power MOSFET is typically separated from the channel region by a thin gate insulating pattern, such as a silicon oxide pattern. Because the gate electrode of the MOSFET is insulated from the channel region by the gate insulating pattern, minimal gate current is required to maintain the MOSFET in its on-state or to switch the MOSFET between its on-state and its off-state. The gate current is kept small during switching because the gate forms a capacitor with the channel region. Thus, only minimal charging and discharging current is required during switching, allowing for less complex gate drive circuitry.

Another well known type semiconductor switching device is the Insulated Gate Bipolar Transistor (“IGBT”), which is a device that combines the high impedance gate of the power MOSFET with the small on-state conduction losses of a power bipolar junction transistor (BJT). An IGBT may be implemented, for example, as a Darlington pair that includes a high voltage n-channel MOSFET at the input and a BJT at the output. The base current of the BJT is supplied through the channel of the MOSFET, thereby allowing a simplified external drive circuit.

There is an increasing demand for high power semiconductor switching devices that can pass large currents in their “on” state and block large voltages (e.g., hundreds or even thousands of volts) in their reverse blocking state. In order to support high current densities and block such high voltages, power MOSFETs and IGBTs typically have a vertical structure with the source and drain on opposite sides of a thick semiconductor layer structure in order to block higher voltage levels. In very high power applications, the semiconductor switching devices are typically formed in wide band-gap semiconductor material systems (herein, the term “wide band-gap semiconductor” encompasses any semiconductor having a band-gap of at least 1.4 eV) such as, for example, silicon carbide (“SiC”), which has a number of advantageous characteristics including, for example, a high electric field breakdown strength, high thermal conductivity, high electron mobility, high melting point and high-saturated electron drift velocity. Relative to devices formed using other semiconductor materials such as, for example, silicon, electronic devices formed using silicon carbide may have the capability of operating at higher temperatures, at high power densities, at higher speeds, at higher power levels and/or under high radiation densities.

### SUMMARY

A semiconductor device according to some embodiments includes a semiconductor layer having a first conductivity type, a well region in the semiconductor layer, the well region having a second conductivity type opposite the first conductivity type, a source region having the first conductivity type in the well region, and an implanted charge compensation region in the semiconductor layer beneath the well region. The source region is adjacent a channel region in the well region.

In some embodiments, the charge compensation region increases a voltage blocking capability of the semiconductor device.

The semiconductor device may further include a gate insulating layer on the semiconductor layer above the channel region, a gate contact on the gate insulating layer, and a first contact on the source region.

The semiconductor device may further include a substrate having the first conductivity type, wherein the semiconductor layer is on the substrate, and a second contact on the substrate.

In some embodiments, the charge compensation region includes non-activated implanted dopant ions.

In some embodiments, the semiconductor layer includes silicon carbide, and the charge compensation region includes hydrogen, aluminum or nitrogen dopant ions.

In some embodiments, the semiconductor layer includes silicon carbide, and the charge compensation region includes inert ions. The inert ions may include He, Ne, and/or Ar ions.

In some embodiments, the semiconductor layer includes silicon carbide, and wherein the charge compensation region includes dopant ions that form deep level traps in the semiconductor layer. The dopant ions may include carbon and/or iron.

The charge compensation region may decrease an electric field strength in the semiconductor layer in an area around the charge compensation region during a voltage blocking operation of the device.

The semiconductor device may further include a doped well contact region in the semiconductor layer adjacent the source region, wherein the well contact region has the second conductivity type and contacts the well region, and wherein the charge compensation region is at least partially provided beneath the well contact region.

The semiconductor device may further include a doped well contact region in the semiconductor layer adjacent the source region, wherein the well contact region has the second conductivity type and contacts the well region, wherein the charge compensation region is not provided directly beneath the well contact region.

In some embodiments, the charge compensation region is spaced apart from the well region in a vertical direction.

The semiconductor device may further include a vertical conduction region adjacent the well region, wherein the charge compensation region is formed beneath a lower corner of the well region near the vertical conduction region.

In some embodiments, the charge compensation region extends past the lower corner of the well region and into the vertical conduction region.

A method of forming a semiconductor device according to some embodiments includes forming a well region in a semiconductor layer, wherein the semiconductor layer has a first conductivity type, and the well region has a second conductivity type opposite the first conductivity type, forming a source region in the well region, wherein the source region has the first conductivity type, wherein the source region is adjacent a channel region in the well region, and implanting ions into the semiconductor layer to form a charge compensation region in the semiconductor layer beneath the well region.

The charge compensation region may increase a voltage blocking capability of the semiconductor device.

In some embodiments, the semiconductor layer includes silicon carbide, and forming the charge compensation region includes implanting aluminum or nitrogen dopant ions into the semiconductor layer.

In some embodiments, the semiconductor layer includes silicon carbide, and the charge compensation region includes dopant ions that form deep level traps in the semiconductor layer. The dopant ions may include carbon and/or iron.

In some embodiments, the semiconductor layer includes silicon carbide, and implanting ions includes implanting inert ions. The inert ions may include He, Ne, and/or Ar ions.

In some embodiments, the charge compensation region decreases an electric field strength in the semiconductor layer in an area around the charge compensation region during a voltage blocking operation of the device.

The method may further include forming a doped well contact region in the semiconductor layer adjacent the source region, wherein the well contact region has the second conductivity type and contacts the well region, wherein the charge compensation region is at least partially formed beneath the well contact region.

The method may further include forming a doped well contact region in the semiconductor layer adjacent the source region, wherein the well contact region has the second conductivity type and contacts the well region, wherein the charge compensation region is not provided directly beneath the well contact region.

In some embodiments, the charge compensation region is spaced apart from the well region in a vertical direction.

The method may further include forming a vertical conduction region adjacent the well region, wherein the charge compensation region is formed beneath a lower corner of the well region near the vertical conduction region.

In some embodiments, the charge compensation region extends past the lower corner of the well region and into the vertical conduction region.

The method may further include forming a gate insulating layer on the semiconductor layer above the channel region, a gate contact on the gate insulating layer, and a first contact on the source region.

The method may further include providing a substrate having the first conductivity type, wherein the semiconductor layer is formed on the substrate, and forming a second contact on the substrate.

### BRIEF DESCRIPTION OF THE DRAWINGS

FIG. 1 is a cross-sectional view of a conventional MOSFET structure.

FIGS. 2A and 2B are cross-sectional views of MOSFET structures including charge compensation/trapping structures according to some embodiments.

FIG. 2C is a graph of dopant concentrations within a MOSFET structure including a charge compensation/trapping structure according to some embodiments.

FIGS. 3 to 7 are cross-sectional views of MOSFET structures including charge compensation/trapping structures according to some embodiments.

FIG. 8 is a block diagram illustrating operations for forming a MOSFET structure including a charge compensation/trapping structure according to some embodiments.

### DETAILED DESCRIPTION OF EMBODIMENTS

Power silicon carbide MOSFETs are in use today for applications requiring high voltage blocking such as voltage blocking of 5,000 volts or more. By way of example, silicon carbide MOSFETs are commercially available that are rated for current densities of 10 A/cm2 or more that will block voltages of at least 10 kV. To form such devices, a plurality of “unit cells” are typically formed, where each unit cell includes a MOSFET transistor. In high power applications, a large number of these unit cells (e.g., hundreds or thousands) are typically provided on a single semiconductor substrate, and a gate electrode pattern is formed on a top side of the semiconductor substrate that acts as the gate electrode for all of the unit cells. The opposite (bottom) side of the semiconductor substrate acts as a common drain for all of the units cells of the device. A plurality of source contacts are formed on source regions in the semiconductor layer structure that are exposed within openings in the gate electrode pattern. These source contacts are also electrically connected to each other to serve as a common source. The resulting device has three terminals, namely a common source terminal, a common drain terminal and a common gate electrode that act as the terminals for the hundreds or thousands of individual unit cell transistors. It will be appreciated that the above description is of an n-type MOSFET; the locations of the drain and source would be reversed for a p-type MOSFET.

For traditional MOSFET structures, such as power MOSFETs using SiC, one potential issue is the presence of a high electrical field at the gate oxide in the center of the junction field effect (JFET) region of the device. A JFET region generally is an active portion of an N-type drift layer which may include an N-type dopant and is located between two P-type wells. The JFET region refers to a region in the drift layer that is in contact with channel regions coming up to the surfaces of the P-type wells responsive to the application of a gate voltage. In a vertical device, the JFET region makes up a vertical conduction path for electrons within the device that includes the N+ source region, the channel region, the N-type drift layer, the substrate, and the drain electrode.

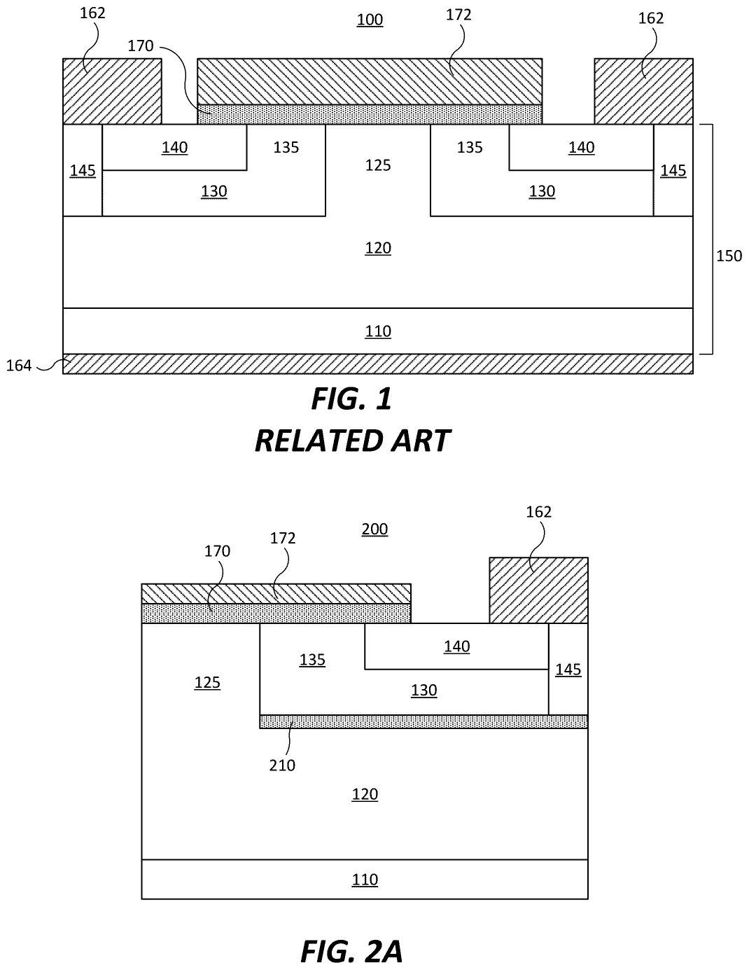

FIG. 1 is a schematic cross-sectional diagram of a unit cell of a conventional semiconductor device 100, with areas of concern identified according to some embodiments described herein.

As shown in FIG. 1, the device 100 may be or include a transistor (e.g., a MOSFET) formed using an n-type silicon carbide semiconductor substrate 110. The substrate 110 may comprise, for example, a single crystal 4H silicon carbide semiconductor substrate that is heavily-doped with n-type impurities (i.e., an n+ silicon carbide substrate). A lightly-doped n-type (n-) silicon carbide drift layer 120 is provided on the substrate 110. Upper portions of the n-type silicon carbide drift layer 120 may be doped p-type by ion implantation to form p-wells 130. Each p-well 130 may be formed by ion implantation, though the embodiments described herein are not limited thereto.

As is known to those skilled in the art, ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer. The ions will implant at different depths into the semiconductor layer so that the predetermined kinetic energy will provide an implant “profile” with varying ion concentrations as a function of depth.

Heavily-doped (n+) n-type silicon carbide source regions 140 may be formed in upper portions of the p-wells 130. The n-type source regions 140 may be formed by ion implantation. The heavily-doped (n+) n-type silicon carbide regions 140 act as source regions for the device 100. P+ well contact regions 145 are formed to extend from the surface of the drift layer 120 into the p-wells 130.

The drift layer 120 and the substrate 110 together act as a common drain region for the device 100. The n-type silicon carbide substrate 110, the n-type silicon carbide drift layer 120, the p-wells 130, and the n-type source regions 140 formed therein may together comprise a semiconductor layer structure 150 of the device 100.

A gate insulating pattern 170 may be formed on the upper surface of the semiconductor layer structure 150. The gate insulating pattern 170 may comprise, for example, a silicon dioxide (SiO2) layer, although other insulating materials, a silicon dioxide (SiO2) layer, although other insulating materials, such as SiOxNy, SixNy, Al2O3 and/or high-K dielectrics such as hafnium oxide, and the like may be used. A gate electrode 172 may be formed on the gate insulating pattern 170 opposite the semiconductor layer structure 150.

Source contacts 162 may be formed on the heavily-doped n-type source regions 140, and a drain contact 164 may be formed on the lower surface of the substrate 110. It will be appreciated that the above description is of an n-type MOSFET. In p-type devices, the locations of the source and drain contacts may be reversed, and the conductivity types of the other n- and p-type regions may be swapped. Accordingly, the source region 140 can be referred to as a “source/drain region” 140.

The voltage blocking characteristics of a vertical power FET device, such as a MOSFET or IGBT, are a key performance factor of the device. Embodiments described herein provide structures and methods for improving the voltage blocking characteristics of a vertical power FET device that includes a p-well region. In particular, some embodiments provide methods that suppress/relieve the electric field concentration beneath or near the p-well by providing charge compensation/trapping regions beneath or near the bottom of the p-well. The charge compensation/trapping regions may be formed, for example, by implantation of ions near the bottom of the p-well. The ions may include dopant ions that are not subsequently activated, or inactive/inert ions, such as He, Ne, or Ar. The dopant ions may include, for example, shallow-level dopant ions, such as Al, P, or N, or deep-level dopant ions, such as Fe, C or H.

While not wishing to be bound by a particular theory of operation, it is believed that implant damage caused by the ion implants creates charge compensation/trapping regions at a specific location within the device structure. These charge compensation/trapping regions are believed to play a role in suppressing/relieving the electric field concentration within the device. By placing these compensation/trapping regions near the bottom of the p-well region, and in particular, near the corner of the p-well region adjacent the JFET region 125 of the device where breakdown typically occurs, the blocking characteristics of the device may be enhanced.

When dopant ions are implanted into a semiconductor crystal, charged ions are accelerated via an electric field having a predetermined energy (typically expressed in keV or MeV) and directed toward the semiconductor crystal, where they become physically implanted into the crystal. The act of implantation causes damage to the crystal lattice of the semiconductor crystal (sometimes referred to as “lattice damage”). Typically, dopant ions are implanted into a semiconductor crystal to change the electrical properties of the semiconductor crystal into, for example, an n-type material or a p-type material, depending on the nature of the ions being implanted. For example, nitrogen or phosphorus ions may be implanted into a silicon carbide crystal to form n-type SiC, while aluminum ions may be implanted into a silicon carbide crystal to form p-type SiC. After implantation of dopant ions, the lattice damage is repaired by annealing, or heat-treating, the semiconductor crystal at a high temperature, which may cause chemical bonds in the semiconductor crystal to be repaired and/or may cause the dopant ions to move into positions within the crystal lattice at which they can become electrically active. In places where the lattice damage is not repaired, electrical “traps” may be formed which can trap or compensate mobile charge carriers (e.g., electrons or holes) within the semiconductor crystal.

According to some embodiments, implant damage caused by the implantation of ions may be left un-repaired, so that electrical traps remain in the semiconductor crystal. It is presently believed that by placing these electrical traps in specific locations within a device structure, they may help to relieve the electric field concentration within the device at those locations. Accordingly, in some embodiments, an activation/repair annealing process may not be performed after implantation of ions to form the charge compensation/trapping region within the device. Charge compensation/trapping regions formed via ion implantation may be referred to herein more concisely as “charge compensation regions.”

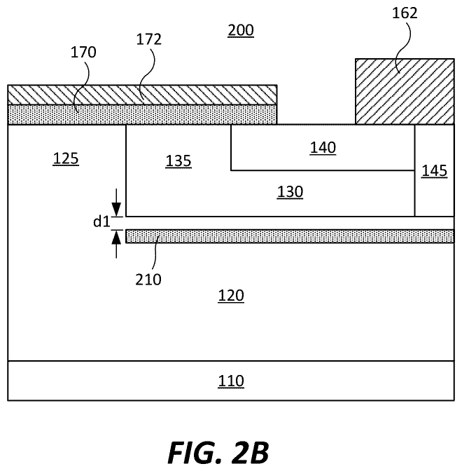

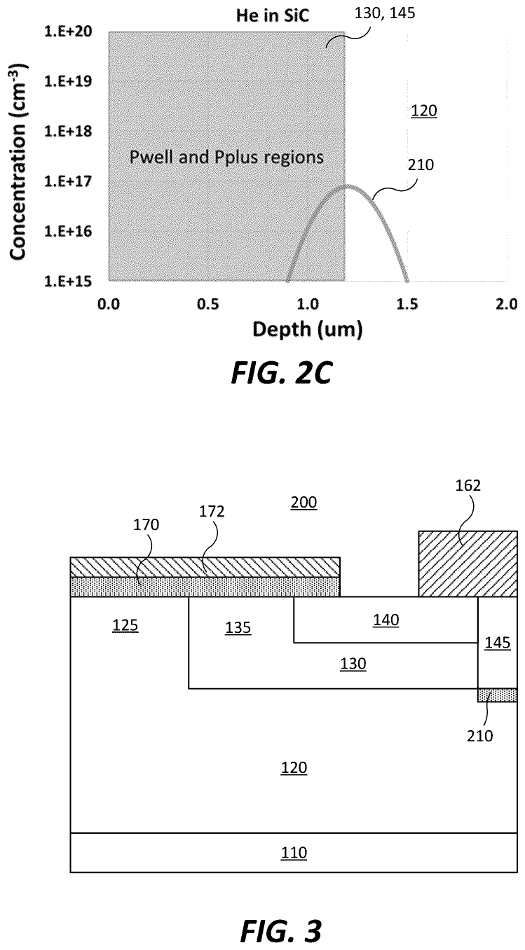

FIG. 2A illustrates a portion of a vertical power FET device 200 according to some embodiments. In particular, the vertical FET power device 200 includes an n-drift layer 120 on a 4H-SiC substrate 110. A p-type p-well region 130 is formed in the drift layer 120, and an n-type source region 140 is formed in the p-well region. A p-well contact region 145 is provided adjacent the source region 140. A channel region 135 is defined between the source region 140 and the JFET region 125 of the drift layer 120.

A source contact 162 is formed on the surface of the semiconductor layer structure 150 and contacts the source region 140 and the p-well contact region 145. A gate dielectric 170 is on the drift layer 120 and a gate contact 172 is on the gate dielectric 170.

A charge compensation region 210 is formed beneath the p-well region 130. As described above, the charge compensation region 210 may be formed by implantation of dopant ions that are not subsequently activated (e.g., via an implant activation anneal), or inactive/inert ions, such as He, Ne, or Ar, where lattice damage from the implantation is not subsequently repaired via annealing. The dopant ions may include, for example, shallow-level dopant ions, such as Al, P, or N, or deep-level dopant ions, such as Fe, C or H.

The charge compensation region 210 maybe provided immediately below the p-well region 130 as illustrated in FIG. 2A, or may be spaced apart from the p-well region 130 in the vertical direction by a distance d1 as illustrated in FIG. 2B. The distance d1 may for example be about 0 microns to about one micron. As described above, while not wishing to be bound by a particular theory of operation, it is believed that implant damage caused by the implantation of dopant ions creates charge compensation region 210 that may help to suppress/relieve the electric field concentration within the device when the device is operating under reverse operating bias conditions. This may improve the blocking characteristics of the device.

FIG. 2C schematically illustrates doping concentrations of the p-well region 130, the p+ contact region 145 and the charge compensation region 210 in a device 200, with depth in the drift layer 120 indicated along the x-axis and doping concentration indicated along the y-axis. As shown in FIG. 2C, The p-well region 130 and the p+ contact region 145 may have doping concentrations in excess of 1 E19 cm⁻³, and may extend to a depth of about 1.2 microns into the drift layer 120 (as in this example, although depths from 0.4 microns to 4 microns could be used). The charge compensation region 210 has a peak doping concentration of about 1 E16 to 1 E18 cm⁻³, which is significantly lower than the doping concentration in the p-well region 130 and the p+ contact region 145. The implant conditions for forming the charge compensation region 210 (e.g., implant angle, implant energy, implant temperature, etc.) may be selected so that the peak doping concentration of the charge compensation region 210 is at or near the interface between the p-well region 130 and the p+ contact region 145 with the drift layer 120. However, as noted above, in some embodiments, the implant conditions for forming the charge compensation region 210 may be selected so that the peak doping concentration of the charge compensation region 210 is spaced apart from the interface between the p-well region 130 and the p+ contact region 145 with the drift layer 120 (i.e., the peak concentration of the charge compensation region 210 is deeper than the p-well region 130 and the p+ contact region 145 within the drift layer 120.

The charge compensation region 210 may be provided in various locations within the device 200 according to some embodiments. For example, as shown in FIG. 3, the charge compensation region 210 may in some embodiments be provided mostly beneath the p+ contact region 140 and not beneath the majority of the p-well region 130.

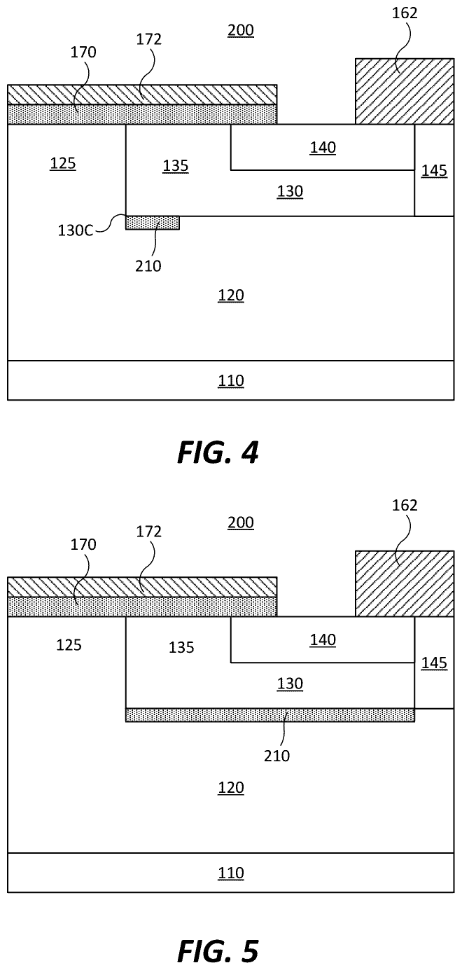

Referring to FIG. 4, in some embodiments, the charge compensation region 210 may be provided directly beneath the p-well region 130 near a corner 130C of the p-well region 130 adjacent the JFET region 125 of the device 200.

Referring to FIG. 5, in some embodiments, the charge compensation region 210 may be provided beneath the p-well region 130 and not directly beneath the p+ contact region 140.

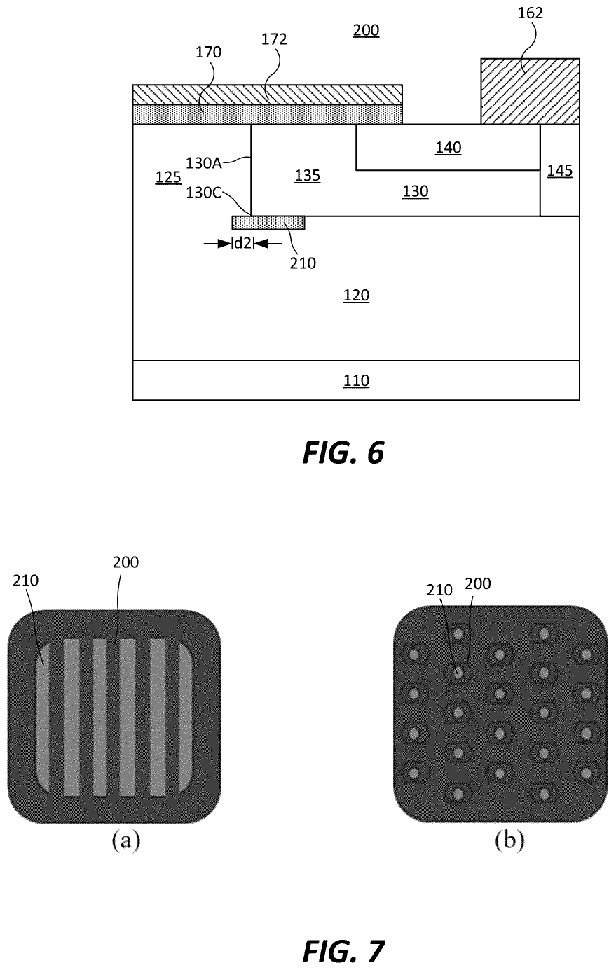

Referring to FIG. 6, in some embodiments, the charge compensation region 210 may be provided beneath the p-well region 130 near a corner 130C of the p-well region 130 adjacent the JFET region 125 of the device 200, and may extend past a sidewall 130A of the p-well region 130 into the JFET region 125 by a distance d2 of about 0 to 1 microns. In the examples shown in FIGS. 3-6, the charge compensation region may touch the edge of the p-well region 130, or may be slightly below it (as shown in FIGS. 2A and 2B).

FIG. 7 illustrates schematic mask layouts of MOSFETs with the implanted charge compensation regions 210. The device should have the He implantation below the p-well regions 130 and/or p+ contact regions 145 inside the active area of a device. In particular, FIG. 7(a) shows a layout scheme for a stripe cell design and FIG. 7(b) shows a layout scheme for a hexagonal cell design. Thus the charge compensation region patterns may be adjusted for varied MOSFET layouts, as described.

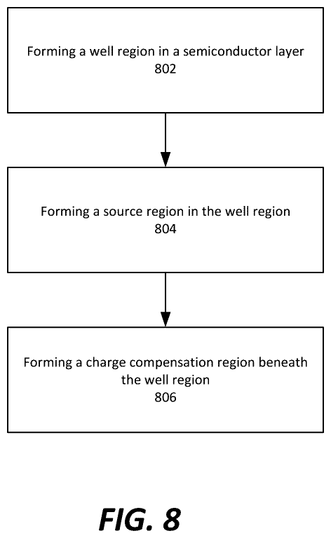

FIG. 8 illustrates operations of forming a semiconductor device 200 structure according to some embodiments. Referring to FIGS. 2A to 6 and 8, the operations include forming ap-well region 130 in a semiconductor layer 120. The semiconductor layer 120 has a first conductivity type (e.g., n-type), and the p-well region 130 has a second conductivity type opposite the first conductivity type (e.g., p-type) (block 802).

A source region 140 is formed in the well region (block 804). The source region 140 has the first conductivity type and is adjacent a channel region 135 in the well region. Ions are implanted into the semiconductor layer 120 to form a charge compensation region 210 in the semiconductor layer 120 beneath the p-well region 130 (block 806). The charge compensation region 210 may increase a voltage blocking capability of the semiconductor device 200. In particular, the charge compensation region 210 may decrease an electric field strength in the semiconductor layer 120 in an area around the charge compensation region 210 during a voltage blocking operation of the device 200.

The semiconductor layer 120 may include silicon carbide, and forming the charge compensation region 210 may include implanting aluminum or nitrogen dopant ions into the semiconductor layer 120.

In some embodiments, the charge compensation region 210 includes dopant ions that form deep level traps in the semiconductor layer 120. For example, the dopant ions may include carbon and/or iron.

In some embodiments, implanting ions comprises implanting inert ions. For example, the inert ions may include He, Ne, and/or Ar ions.

The method may further include forming a doped well contact region 145 in the semiconductor layer 120 adjacent the source region 140. The well contact region 145 has the second conductivity type and contacts the p-well region 130. The charge compensation region 210 may be at least partially formed beneath the well contact region 145 in some embodiments.

In some embodiments, the charge compensation region 210 is not provided directly beneath the well contact region 145.

In some embodiments, the charge compensation region 210 is spaced apart from the p-well region 130 in a vertical direction.

The method may further include forming a vertical conduction region 125 adjacent the p-well region 130. The charge compensation region 210 may be formed beneath a lower corner 130C of the p-well region 130 near the vertical conduction region 125 in some embodiments. In some embodiments, the charge compensation region 210 may extend past the lower corner 130C of the p-well region 130 and into the vertical conduction region 125.

The method may further include forming a gate insulating layer 170 on the semiconductor layer 120 above the channel region 135, a gate contact 172 on the gate insulating layer 170, and a source contact 162 on the source region.

The method may further include providing a substrate 110 having the first conductivity type, wherein the semiconductor layer 120 is formed on the substrate, and forming a drain contact 164 (FIG. 1) on the substrate 110.

Embodiments have been described above with reference to the accompanying drawings, in which embodiments of the inventive concepts are shown. The inventive concepts disclosed herein may, however, be embodied in many different forms and should not be construed as limited to the embodiments set forth herein. Rather, these embodiments are provided so that this disclosure will be thorough and complete, and will fully convey the scope of the inventive concepts to those skilled in the art. In the drawings, the size and relative sizes of layers and regions may be exaggerated for clarity. It will be understood that when an element or layer is referred to as being “on,” “connected to,” or “coupled to” another element or layer, it can be directly on, connected or coupled to the other element or layer, or intervening elements or layers may be present. In contrast, when an element is referred to as being “directly on,” “directly connected to,” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the inventive concepts.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the inventive concepts. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, elements, and/or components, but do not preclude the presence or addition of one or more other features, elements, components, and/or groups thereof

Embodiments are described herein with reference to cross-sectional illustrations that are schematic illustrations. As such, variations from the shapes of the illustrations as a result, for example, of manufacturing techniques and/or tolerances, are to be expected. Thus, embodiments of the inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the inventive concepts.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the inventive concepts may include additional and/or intervening layers, structures, or elements, and/or particular layers, structures, or elements may be deleted. Although a few exemplary embodiments have been described, those skilled in the art will readily appreciate that many modifications are possible in the exemplary embodiments without materially departing from the novel teachings and advantages of the inventive concepts. Accordingly, all such modifications are intended to be included within the scope of the inventive concepts as defined in the claims. Therefore, it is to be understood that the foregoing is illustrative of the inventive concepts and is not to be construed as limited to the specific embodiments disclosed, and that modifications to the disclosed embodiments, as well as other embodiments, are intended to be included within the scope of the inventive concepts.

1. A semiconductor device, comprising:
a semiconductor layer having a first conductivity type;
a well region in the semiconductor layer, the well region having a second conductivity type opposite the first conductivity type;
a source region in the well region, wherein the source region has the first conductivity type, wherein the source region is adjacent a channel region in the well region; and
an implanted charge compensation region in the semiconductor layer beneath the well region.

2. The semiconductor device of claim 1, wherein the charge compensation region increases a voltage blocking capability of the semiconductor device.

3. The semiconductor device of claim 1, further comprising a gate insulating layer on the semiconductor layer above the channel region, a gate contact on the gate insulating layer, and a first contact on the source region.

4. The semiconductor device of claim 3, further comprising a substrate having the first conductivity type, wherein the semiconductor layer is on the substrate, and a second contact on the substrate.

5. The semiconductor device of claim 1, wherein the charge compensation region comprises non-activated implanted dopant ions.

6. The semiconductor device of claim 1, wherein the semiconductor layer comprises silicon carbide, and wherein the charge compensation region comprises hydrogen, aluminum or nitrogen dopant ions.

7. The semiconductor device of claim 1, wherein the semiconductor layer comprises silicon carbide, and wherein the charge compensation region comprises inert ions.

8. The semiconductor device of claim 7, wherein the inert ions comprise He, Ne, and/or Ar ions.

9. The semiconductor device of claim 1, wherein the semiconductor layer comprises silicon carbide, and wherein the charge compensation region comprises dopant ions that form deep level traps in the semiconductor layer.

10. The semiconductor device of claim 5, wherein the dopant ions comprise carbon and/or iron.

11. The semiconductor device of claim 1, wherein the charge compensation region decreases an electric field strength in the semiconductor layer in an area around the charge compensation region during a voltage blocking operation of the device.

12. The semiconductor device of claim 1, further comprising a doped well contact region in the semiconductor layer adjacent the source region, wherein the well contact region has the second conductivity type and contacts the well region, wherein the charge compensation region is at least partially provided beneath the well contact region.

13. The semiconductor device of claim 1, further comprising a doped well contact region in the semiconductor layer adjacent the source region, wherein the well contact region has the second conductivity type and contacts the well region, wherein the charge compensation region is not provided directly beneath the well contact region.

14. The semiconductor device of claim 1, wherein the charge compensation region is spaced apart from the well region in a vertical direction.

15. The semiconductor device of claim 1, further comprising a vertical conduction region adjacent the well region, wherein the charge compensation region is formed beneath a lower corner of the well region near the vertical conduction region.

16. The semiconductor device of claim 15, wherein the charge compensation region extends past the lower corner of the well region and into the vertical conduction region.

17. A method of forming a semiconductor device, comprising:
forming a well region in a semiconductor layer, wherein the semiconductor layer has a first conductivity type, and the well region has a second conductivity type opposite the first conductivity type;
forming a source region in the well region, wherein the source region has the first conductivity type, wherein the source region is adjacent a channel region in the well region; and
implanting ions into the semiconductor layer to form a charge compensation region in the semiconductor layer beneath the well region.

18. The method of claim 17, wherein the charge compensation region increases a voltage blocking capability of the semiconductor device.

19. The method of claim 17, wherein the semiconductor layer comprises silicon carbide, and wherein forming the charge compensation region comprises implanting aluminum or nitrogen dopant ions into the semiconductor layer.

20. The method of claim 17, wherein the semiconductor layer comprises silicon carbide, and wherein the charge compensation region comprises dopant ions that form deep level traps in the semiconductor layer.

21. The method of claim 20, wherein the dopant ions comprise carbon and/or iron.

22. The method of claim 17, wherein the semiconductor layer comprises silicon carbide, and wherein implanting ions comprises implanting inert ions.

23. The method of claim 22, wherein the inert ions comprise He, Ne, and/or Ar ions.

24. The method of claim 17, wherein the charge compensation region decreases an electric field strength in the semiconductor layer in an area around the charge compensation region during a voltage blocking operation of the device.

25. The method of claim 17, further comprising forming a doped well contact region in the semiconductor layer adjacent the source region, wherein the well contact region has the second conductivity type and contacts the well region, wherein the charge compensation region is at least partially formed beneath the well contact region.

26. The method of claim 17, further comprising forming a doped well contact region in the semiconductor layer adjacent the source region, wherein the well contact region has the second conductivity type and contacts the well region, wherein the charge compensation region is not provided directly beneath the well contact region.

27. The method of claim 17, wherein the charge compensation region is spaced apart from the well region in a vertical direction.

28. The method of claim 17, further comprising forming a vertical conduction region adjacent the well region, wherein the charge compensation region is formed beneath a lower corner of the well region near the vertical conduction region.

29. The method of claim 28, wherein the charge compensation region extends past the lower corner of the well region and into the vertical conduction region.

30. The method of claim 17, further comprising forming a gate insulating layer on the semiconductor layer above the channel region, a gate contact on the gate insulating layer, and a first contact on the source region.

31. The method of claim 30, further comprising providing a substrate having the first conductivity type, wherein the semiconductor layer is formed on the substrate, and
forming a second contact on the substrate.
